(19) United States
(12) Patent Application Publication
(10) Pub. No.: US 2025/0091024 A1
(43) Pub. Date: Mar. 20, 2025

(54) OPENING/CLOSING MECHANISM, EXHAUST SWITCHING MECHANISM, AND SUBSTRATE PROCESSING DEVICE

(71) Applicant: SCREEN Holdings Co., Ltd., Kyoto (JP)

(72) Inventor: Chiaki MORIYA, Kyoto (JP)

(21) Appl. No.: 18/890,722

(22) Filed: Sep. 19, 2024

(30) Foreign Application Priority Data
Sep. 20, 2023 (JP) 2023-152516

(51) Int. Cl. B01J 3/02

(52) U.S. Cl. CPC B01J 3/02; B01J 2204/005

(57) ABSTRACT

An opening/closing mechanism includes a base member that can be attached to attachment openings of a switching box, an upper support member provided on an upper surface of the base member, an actuator, a rod extended downward from the actuator while penetrating the base member and moved in an up-down direction by the actuator, a lower support member provided on a lower surface of the base member, a lid member provided below the base member and capable of closing a communication port, and a first link and a second link provided below the base member and configured to connect the rod, the lower support member, and the lid member. The movement of the rod is transmitted to the lid member via the first link and the second link, so that the lid member is switched between an open state and a closed state.

### CROSS-REFERENCE TO RELATED APPLICATIONS

This application claims priority to Japanese Patent Application No. 2023-152516 filed Sep. 20, 2023, the subject matter of which is incorporated herein by reference in entirety.

### BACKGROUND

### Technical Field

The present invention relates to an opening/closing mechanism used in an exhaust switching mechanism for switching an exhaust path from a processing chamber for processing a substrate to any of a plurality of exhaust pipes, an exhaust switching mechanism, and a substrate processing device. Examples of the substrate include, for example, a semiconductor substrate, a substrate for a flat panel display (FPD), a glass substrate for a photomask, a substrate for an optical disk, a substrate for a magnetic disk, a ceramic substrate, and a substrate for a solar cell. Examples of the FPD include a liquid crystal display device and an organic electroluminescence (EL) display device.

### Related Art

The substrate processing device includes a transport space in which a transport robot is provided, and four towers provided along the transport space (see e.g., JP 2021-136435 A). Each of the four towers includes six processing chambers arranged in an up-down direction (vertical direction). Each of the four towers is provided with three exhaust pipes extending in the up-down direction. For example, the six processing chambers of the first tower are each connected to three exhaust pipes by way of an exhaust switching mechanism. As a result, the exhaust path from the processing chamber selectively communicates with any of the three exhaust pipes.

### SUMMARY

However, the conventional example may have the following problems. When the substrate processing device includes, for example, 24 processing chambers, 24 exhaust switching mechanisms are provided. In addition, in a case where a predetermined processing chamber selectively communicates with, for example, any of the three exhaust pipes, three opening/closing mechanisms are provided with respect to one exhaust switching mechanism. Therefore, for example, 72 opening/closing mechanisms are provided. For example, if it is difficult to attach and detach the opening/closing mechanism in the exhaust switching mechanism, there is a possibility that the assembly or maintenance time of the exhaust switching mechanism and the substrate processing device becomes longer.

The present invention has been made in view of such circumstances, and an object of the present invention is to provide an opening/closing mechanism and an exhaust switching mechanism that are easily attached, as well as a substrate processing device.

In order to achieve such an object, the present invention has the following configuration. That is, an opening/closing mechanism according to the present invention is an opening/closing mechanism that is used in an exhaust switching mechanism that connects a processing chamber to any of a plurality of exhaust pipes via a switching box, and that opens/closes any one of a plurality of communication ports for communicating the switching box and the plurality of exhaust pipes, the opening/closing mechanism including, a base member attachable to each of a plurality of attachment openings provided in a ceiling wall of the switching box in correspondence with the plurality of communication ports, an upper support member provided on an upper surface of the base member, an actuator attached to the upper support member, a rod extending downward from the actuator while penetrating the base member, the rod being moved in an up-down direction by the actuator, a lower support member provided on a lower surface of the base member, a lid member provided below the base member and configured to close the one of the communication ports, and a link member provided below the base member to connect the rod, the lower support member, and the lid member, in which: the lid member is switched between an open state and a closed state when movement of the rod in the up-down direction is transmitted to the lid member via the link member.

According to the opening/closing mechanism of the present invention, the base member that can be attached to each of the plurality of attachment openings provided in the ceiling wall of the switching box in correspondence with the plurality of communication ports is provided. The base member is integrally provided with the upper support member, the actuator, the rod, the lid member, the lower support member, and the link member. Thus, the integrated opening/closing mechanism can be attached to the switching box. Therefore, attachment of the opening/closing mechanism can be facilitated.

Furthermore, preferably, in the opening/closing mechanism described above, the link member includes a first link having an upper end portion coupled to a lower end portion of the lower support member to be rotatable about a first horizontal axis passing through a portion coupled to the lower support member, the first link having a lower end portion coupled to a back surface of the lid member, and a second link having an upper end portion coupled to the rod to be rotatable about a second horizontal axis passing through a lower end portion of the rod, the second link having a lower end portion coupled to the first link to be rotatable about a third horizontal axis passing through the first link; and each of the second horizontal axis and the third horizontal axis is parallel to the first horizontal axis.

The base member is integrally provided with the lower support member, the first link, and the second link together with the lid member and the like. Thus, the integrated opening/closing mechanism can be attached to the switching box.

Furthermore, preferably, the opening/closing mechanism described above further includes a bellows extending in the up-down direction, a lower member provided at a lower end of the bellows and attached to the base member, and an upper member provided at an upper end of the bellows to close an upper end of a cavity of the bellows, in which the rod includes a first rod and a second rod, the first rod extends downward from the actuator, and a lower end of the first rod is coupled to the upper member, an upper end of the second rod is coupled to the upper member, and the second rod penetrates the lower member and the base member while passing through the cavity of the bellows.

The lower member provided at the lower end of the bellows is attached to the base member. In addition, the upper member provided at the upper end of the bellows closes the upper end of the cavity of the bellows. Furthermore, the first rod is coupled to the second rod by way of the upper member. The second rod penetrates the lower member and the base member while passing through the cavity of the bellows. With such a bellows and its peripheral structure, even if there is a sliding portion of the rod with respect to the base member, gas in the switching box can be prevented from leaking.

Furthermore, in the opening/closing mechanism described above, the lower end of the first rod is preferably coupled to the upper member via a joint that absorbs eccentricity and deflection angle between the first rod and the second rod.

The joint interposed between the lower end of the first rod and the upper member can absorb eccentricity and deflection angle between the first rod and the second rod.

Furthermore, in the opening/closing mechanism described above, a packing is preferably disposed on a peripheral edge portion of a surface of the lid member.

When the lid member is in the closed state, airtightness is improved. For example, mixture of gas containing a chemical solution (chemical solution atmosphere) into another exhaust line can be prevented. As a result, for example, when a part of the organic exhaust line is made of metal such as stainless steel, it is possible to prevent corrosion of the metal portion due to mixing of the acidic exhaust air.

In addition, an exhaust switching mechanism according to the present invention is an exhaust switching mechanism that switches an exhaust path from a processing chamber to any of a plurality of exhaust pipes, the exhaust switching mechanism including a switching box that connects the processing chamber to the plurality of exhaust pipes; and a plurality of opening/closing mechanisms that individually opens/closes a plurality of communication ports for communicating the switching box and the plurality of exhaust pipes, the plurality of opening/closing mechanisms being attached to a plurality of attachment openings provided in a ceiling wall of the switching box in correspondence with the plurality of communication ports, in which each of the plurality of opening/closing mechanisms includes a base member attachable to each of the plurality of attachment openings, an upper support member provided on an upper surface of the base member, an actuator attached to the upper support member, a rod extending downward from the actuator while penetrating the base member, the rod being moved in an up-down direction by the actuator, a lower support member provided on a lower surface of the base member, a lid member provided below the base member and configured to close a corresponding one of the plurality of communication ports, and a link member provided below the base member to connect the rod, the lower support member, and the lid member; and the lid member is switched between an open state and a closed state when movement of the rod in the up-down direction is transmitted to the lid member via the link member.

In addition, a substrate processing device for processing a substrate according to the present invention includes an exhaust switching mechanism described above, the processing chamber, a holding unit provided in the processing chamber and holding the substrate in a horizontal posture, a nozzle provided in the processing chamber and discharging a chemical solution to the substrate held by the holding unit, and the plurality of exhaust pipes provided on a side of the processing chamber and extending in an up-down direction.

According to the opening/closing mechanism, the exhaust switching mechanism, and the substrate processing device according to the present invention, attachment of the opening/closing mechanism can be facilitated.

### BRIEF DESCRIPTION OF DRAWINGS

For the purpose of illustrating the invention, there are shown in the drawings several forms which are presently preferred, it being understood, however, that the invention is not limited to the precise arrangement and instrumentalities shown.

FIG. 1 is a plan view illustrating a schematic configuration of a substrate processing device according to a example;

FIG. 2 is a longitudinal cross-sectional view of the substrate processing device as viewed as indicated by an arrow A-A in FIG. 1;

FIG. 3 is a transverse cross-sectional view illustrating a processing chamber and an exhaust switching mechanism;

FIG. 4 is a longitudinal cross-sectional view illustrating the processing chamber and the exhaust switching mechanism;

FIG. 5 is a plan view illustrating three attachment openings formed in a ceiling wall of a switching box;

FIG. 6 is a side view illustrating a state in which three opening/closing mechanisms are attached to the switching box;

FIG. 7A is a side view illustrating an opening/closing mechanism integrally configured with a base member as a base, and FIG. 7B is a view illustrating a surface of a lid member of the opening/closing mechanism;

FIG. 8A is a longitudinal cross-sectional view illustrating the opening/closing mechanism when the lid member is in the closed state, and

FIG. 8B is a longitudinal cross-sectional view illustrating the opening/closing mechanism when the lid member is in the open state;

FIG. 9A is a longitudinal cross-sectional view illustrating a configuration of the bellows and its periphery when the opening/closing mechanism is in the closed state, and FIG. 9B is a longitudinal cross-sectional view illustrating a configuration of the bellows and its periphery when the opening/closing mechanism is in the open state; and

FIG. 10 is a transverse cross-sectional view illustrating a processing chamber and an exhaust switching mechanism according to a modified example.

### DETAILED DESCRIPTION

### Examples

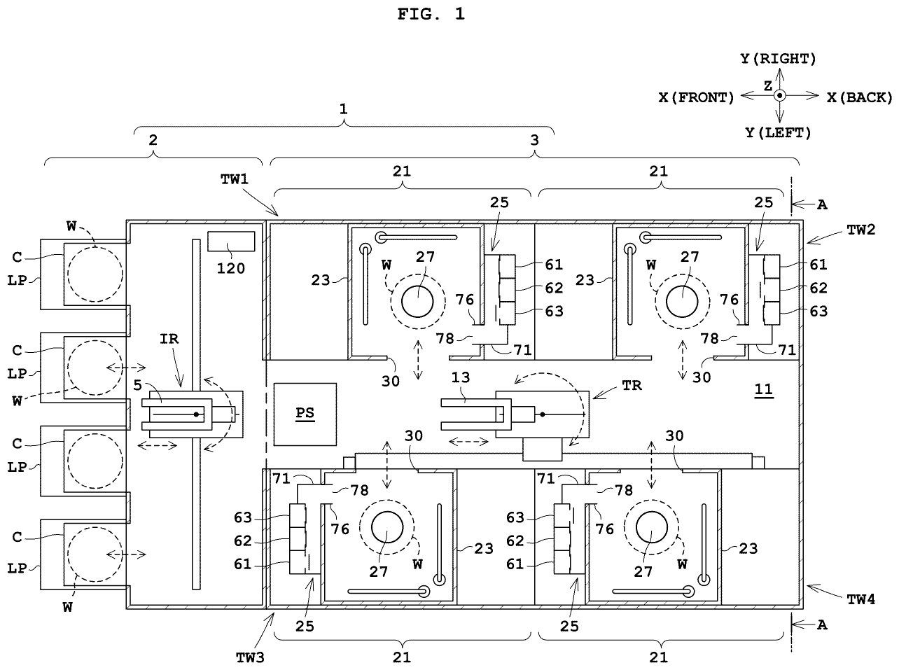

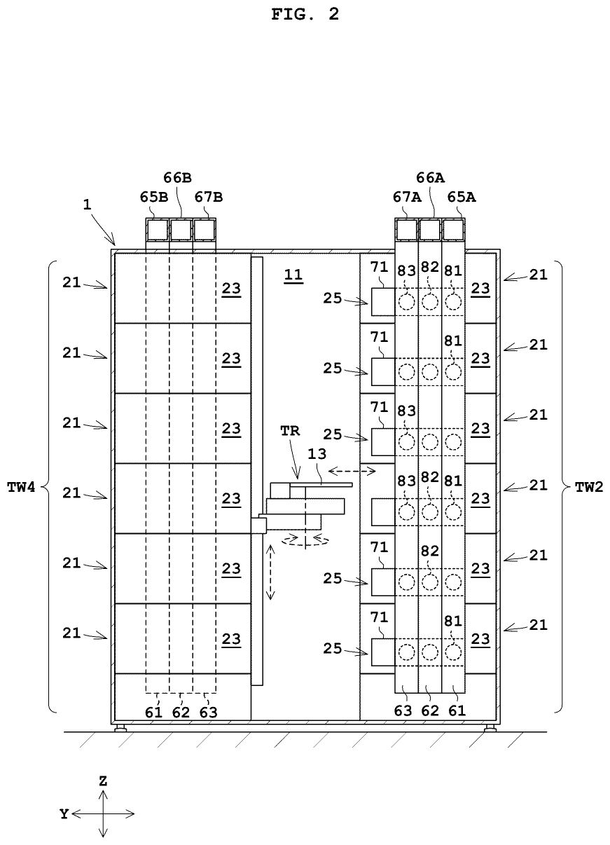

Hereinafter, examples of the present invention will be described with reference to the drawings. FIG. 1 is a plan view (or transverse cross-sectional view) illustrating a schematic configuration of a substrate processing device 1 according to an example. FIG. 2 is a longitudinal cross-sectional view of the substrate processing device when viewed as indicated by an arrow A-A illustrated in FIG. 1.

### <1. Substrate Processing Device>

Reference is now made to FIG. 1. The substrate processing device 1 is a sheet type (single substrate type) device that processes the substrates W one by one. The substrate processing device 1 includes an indexer block 2 and a processing block 3.

In the present specification, for the sake of convenience, a direction in which the indexer block 2 and the processing block 3 are arranged is referred to as a “front-back direction X”. The front-back direction X is horizontal. For example, a direction from the processing block 3 toward the indexer block 2 in the front-back direction X is referred to as a “front side”. A direction opposite to the front side is referred to as a “back side”. A horizontal direction orthogonal to the front-back direction X is referred to as a “width direction Y”. One direction in the “width direction Y” is appropriately referred to as a “right side”. A direction opposite to the right side is referred to as a “left side”. A direction perpendicular to the horizontal direction is referred to as an “up-down direction Z”. In each drawing, front, back, right, left, top, and bottom are appropriately shown for reference.

### <2. Indexer Block>

The indexer block 2 includes a plurality of (for example, four) load ports LP and an indexer robot IR. The load port LP is used to carry in and carry out the carrier C. The carrier C is placed on the load port LP. The load port LP is disposed on the outer side of the indexer block 2.

The carrier C accommodates a plurality of (for example, 25) substrates W. As the carrier C, for example, a front opening unify pod (FOUP) is used, but the carrier C is not limited thereto. The substrate W is formed in, for example, a disk shape.

The indexer robot IR is disposed on the inner side of the indexer block 2. The indexer robot IR transports the substrate W between, for example, four carriers C placed on four load ports LP and a substrate placing portion (shelf) PS described later. The indexer robot IR includes a hand 5. The hand 5 is movable and holds one substrate W. The indexer robot IR moves the hand 5 holding one substrate W in the horizontal direction (the front-back direction X and the width direction Y) and the up-down direction Z. Furthermore, the indexer robot IR rotates the hand 5 about the vertical axis.

### <3. Processing Block>

The processing block 3 includes a transport robot TR, a substrate placing portion PS, and four towers TW1 to TW4. The transport robot TR and the substrate placing portion PS are provided in a transport space 11 extending in the front-back direction X. The transport space 11 extends linearly to the back side from the indexer block 2. The transport robot TR transports the substrate W between the substrate placing portion PS and each processing unit 21 (described later) of the four towers TW1 to TW4. The transport robot TR includes a hand 13. The hand 13 is movable and holds one substrate W in a horizontal posture. The transport robot TR moves the hand 13 holding one substrate W in the horizontal direction (the front-back direction X and the width direction Y) and the up-down direction Z. Furthermore, the transport robot TR rotates the hand 13 about the vertical axis. The substrate placing portion PS is disposed between the indexer robot IR and the transport robot TR.

The first tower TW1 and the second tower TW2 are arranged in the front-back direction X along the transport space 11. Similarly, the third tower TW3 and the fourth tower TW4 are arranged in the front-back direction X along the transport space 11.

In addition, in the width direction Y, the two towers TW1 and TW2 are arranged to face the two towers TW3 and TW4 via the transport space 11. That is, the two towers TW1 and TW2 are arranged on the right side of the transport space 11. In addition, the two towers TW3 and TW4 are arranged on the left side of the transport space 11.

Each of the four towers TW1 to TW4 includes six processing units 21 arranged in the up-down direction Z. That is, the processing block 3 includes twenty-four processing units 21. Note that FIG. 2 shows that, for example, two towers TW2 and TW4 each include six processing units 21 arranged in the up-down direction Z.

Note that the processing block 3 includes four towers TW1 to TW4. In this regard, the processing block 3 may include one or two or more towers. Furthermore, each of the towers TW1 to TW4 include six processing units 21. In this regard, each of the towers TWI to TW4 may include one processing unit 21 or two or more processing units 21 arranged in the up-down direction Z.

### <3-1. Processing Chamber>

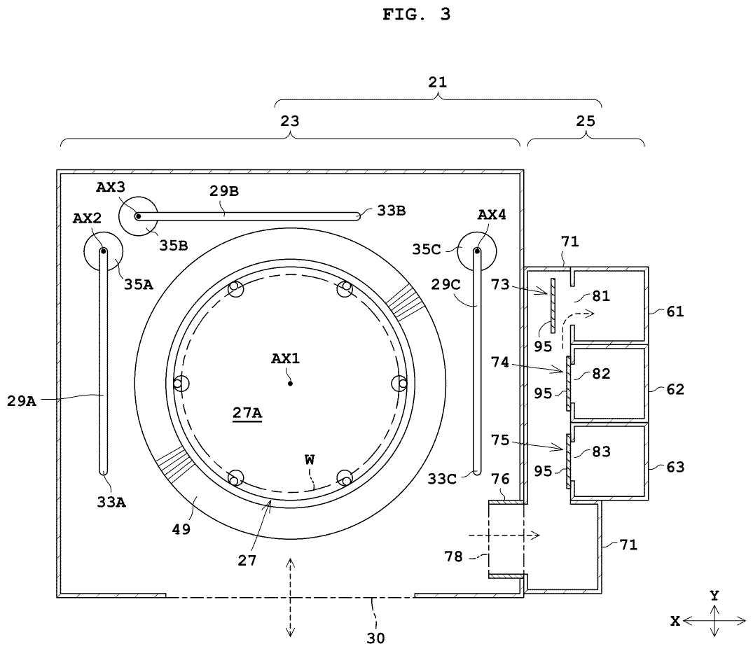

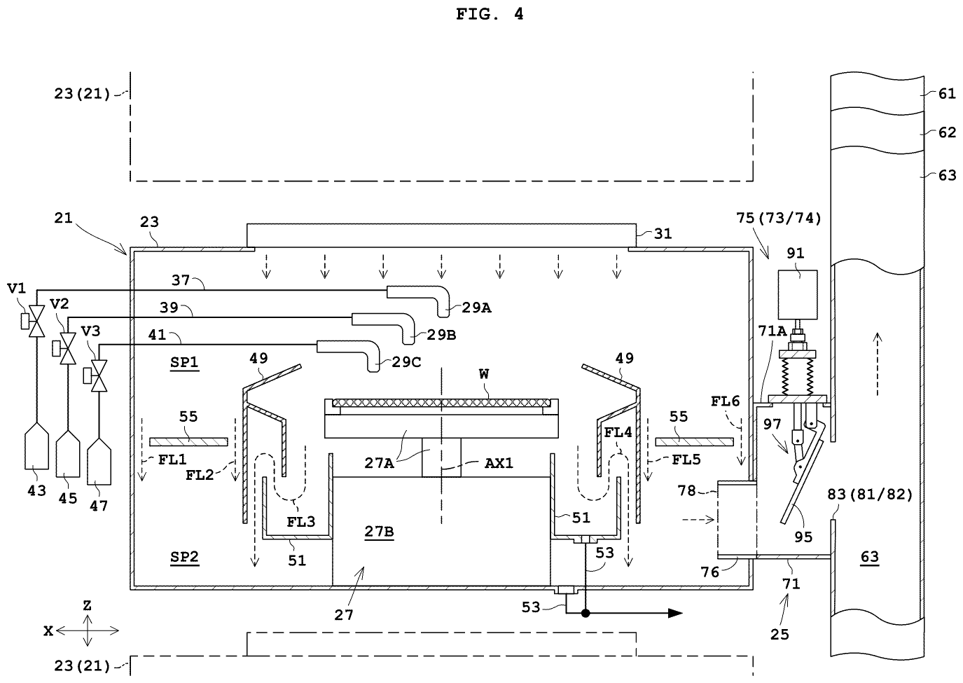

As illustrated in FIG. 1, each processing unit 21 includes a processing chamber 23 and an exhaust switching mechanism 25. FIG. 3 is a transverse cross-sectional view illustrating the processing chamber 23 and the exhaust switching mechanism 25. FIG. 4 is a longitudinal cross-sectional view illustrating the processing chamber 23 and the exhaust switching mechanism 25.

The processing chamber 23 processes the substrates W one by one. The processing chamber 23 includes a holding and rotating unit 27, three nozzles 29A, 29B, and 29C, a substrate transport port 30, and a fan filter unit 31 (see FIG. 4). The holding and rotating unit 27 and the three nozzles 29A, 29B, and 29C are each provided in the processing chamber 23. As illustrated in FIG. 4, the fan filter unit 31 is provided on the ceiling of the processing chamber 23. The fan filter unit 31 supplies clean air (gas) into the processing chamber 23.

The substrate transport port 30 is disposed facing the transport space 11. The substrate W is transported onto the holding and rotating unit 27 through the substrate transport port 30. The holding and rotating unit 27 rotates the substrate W about the vertical axis AX1 while holding the substrate W in a horizontal posture. Specifically, the holding and rotating unit 27 includes a spin chuck 27A that holds the substrate W in a horizontal posture and an electric motor 27B that rotates the spin chuck 27A about the vertical axis AX1. The spin chuck 27A may be a chuck that holds the substrate W by sandwiching the side surface of the substrate W with three or more holding pins. Furthermore, the spin chuck 27A may be a chuck that holds the lower surface of the substrate W by vacuum suction.

Each of the three nozzles 29A, 29B, and 29C discharges chemical solutions onto the substrate W held by the holding and rotating unit 27. The three nozzles 29A, 29B, and 29C discharge the first chemical solution, the second chemical solution, and the third chemical solution. For example, the first nozzle 29A discharges the first chemical solution, and the second nozzle 29B discharges the second chemical solution. The third nozzle 29C discharges the third chemical solution. The first chemical solution, the second chemical solution, and the third chemical solution are different in type from each other. Note that when the first chemical solution, the second chemical solution, and the third chemical solution are not particularly distinguished, they are referred to as “chemical solution”.

The first chemical solution is classified, for example, as an acidic liquid (acid-based chemical solution). The first chemical solution contains, for example, at least one of hydrofluoric acid, hydrochloric acid hydrogen peroxide solution, sulfuric acid, sulfuric acid hydrogen peroxide solution, fluoronitric acid (mixed solution of hydrofluoric acid and nitric acid), and hydrochloric acid.

The second chemical solution is classified into, for example, an alkaline solution (alkaline chemical solution). The second chemical solution contains, for example, at least one of ammonia hydrogen peroxide water (SC1), ammonia water, an ammonium fluoride solution, and tetramethylammonium hydroxide (TMAH).

The third chemical solution is classified into, for example, an organic liquid (organic-based chemical solution). The organic liquid contains at least one of isopropyl alcohol (IPA), methanol, ethanol, hydrofluoroether (HFE), and acetone.

Each of the nozzles 29A, 29B, and 29C has a linearly extending tube shape. The nozzles 29A, 29B, and 29C include distal end portions 33A, 33B, and 33C, respectively. Each of the distal end portions 33A, 33B, and 33C has a discharge port (not illustrated) for discharging a chemical solution.

The processing chamber 23 further includes three rotation driving units 35A, 35B, and 35C. The three rotation driving units 35A, 35B, and 35C are connected to the three basal end portions of the three nozzles 29A, 29B, and 29C, respectively. Each rotation driving unit 35A, 35B, and 35C includes, for example, an electric motor. The first rotation driving unit 35A rotates the first nozzle 29A about the vertical axis AX2. The second rotation driving unit 35B rotates the second nozzle 29B about the vertical axis AX3. The third rotation driving unit 35C rotates the third nozzle 29C about the vertical axis AX4.

As illustrated in FIG. 4, the processing chamber 23 further includes three piping 37,39, and 41. One end of the first piping 37 is connected to the first nozzle 29A. The other end of the first piping 37 is connected to a first chemical solution supply source 43. The first piping 37 is provided with an open/close valve V1. When the open/close valve V1 is opened, the first chemical solution is sent from the first chemical solution supply source 43 to the first piping 37, and the first chemical solution is discharged from the first nozzle 29A.

Similarly, one end of the second piping 39 is connected to the second nozzle 29B. The other end of the second piping 39 is connected to a second chemical solution supply source 45. The second piping 39 is provided with an open/close valve V2. When the open/close valve V2 is opened, the second chemical solution is discharged from the second nozzle 29B. Similarly, one end of the third piping 41 is connected to the third nozzle 29C. The other end of the third piping 41 is connected to a third chemical solution supply source 47. The third piping 41 is provided with an open/close valve V3. When the open/close valve V3 is opened, the third chemical solution is discharged from the third nozzle 29C.

The processing chamber 23 further includes an upper cup 49 and a lower cup 51. Each of the upper cup 49 and the lower cup 51 is formed in a hollow cylindrical shape. As illustrated in FIGS. 3 and 4, the upper cup 49 and the lower cup 51 are disposed so as to surround side surfaces of the substrate W and the spin chuck 27A. The upper cup 49 is disposed above the lower cup 51. The upper cup 49 moves up and down with respect to the lower cup 51, the substrate W, and the spin chuck 27A by a driving unit (not illustrated).

In addition, the upper cup 49 receives the chemical solution scattered from the substrate W due to rotation of the substrate W or the like, and guides the chemical solution to the lower cup 51. The lower cup 51 is provided with a liquid discharge pipe 53 at the bottom. The lower cup 51 discharges the chemical solution by the liquid discharge pipe 53 while accommodating the chemical solution fed from the upper cup 49 and the like. Note that the liquid discharge pipe 53 is also connected to the bottom of the processing chamber 23.

The processing chamber 23 includes a partition plate 55 that partitions the internal upper space SP1 and lower space SP2. The air supplied from the fan filter unit 31 is sent from the upper space SP1 to the lower space SP2 while flowing through the inner side and the outer side of the upper cup 49 as in flows FL1, FL2, FL3, FL4, FL5, and FL6 indicated by broken lines in FIG. 4. Then, the air is sent from the lower space SP2 of the processing chamber 23 to any of the three exhaust pipes 61, 62, and 63 (described later) via an exhaust switching mechanism 25 described later. Note that in FIG. 3, illustration of the partition plate 55 is omitted.

### <3-2. Three Exhaust Pipes>

Three exhaust pipes 61, 62, and 63 extending in the up-down direction Z are provided on the side of each processing chamber 23. Specifically, the three exhaust pipes 61, 62, and 63 are provided in each of the four towers TW1 to TW4. For example, as illustrated in FIG. 2, the three exhaust pipes 61, 62, and 63 are provided on the sides of the six processing chambers 23 of the second tower TW2. Each of the three exhaust pipes 61, 62, and 63 extends in the up-down direction Z. In each of the four towers TW1 to TW4, the three exhaust pipes 61, 62, and 63 are arranged side by side in the width direction Y.

As illustrated in FIG. 2, six horizontal exhaust pipes 65A, 66A, 67A, 65B, 66B, and 67B are provided on the roof of the substrate processing device 1. The six exhaust pipes 61, 62, and 63 of the two towers TWI and TW2 are connected to the three horizontal exhaust pipes 65A, 66A, and 67A. In addition, the six exhaust pipes 61, 62, and 63 of the two towers TW3 and TW4 are connected to the three horizontal exhaust pipes 65B, 66B, and 67B. For example, an upper end of the first exhaust pipe 61 of the first tower TW1 and the upper end of the first exhaust pipe 61 of the second tower TW2 are connected to the horizontal exhaust pipe 65A. Similarly, the second exhaust pipe 62 of the first tower TW1 and the second exhaust pipe 62 of the second tower TW2 are connected to the horizontal exhaust pipe 66A. In addition, the third exhaust pipe 63 of the first tower TW1 and the third exhaust pipe 63 of the second tower TW2 are connected to the horizontal exhaust pipe 67A.

### <3-3. Exhaust Switching Mechanism>

As described above, each of the twenty-four processing units 21 includes the exhaust switching mechanism 25. The exhaust switching mechanism 25 connects the processing chamber 23 to any one of the three exhaust pipes 61, 62, and 63 by way of the switching box 71. That is, the exhaust switching mechanism 25 switches the exhaust path from the processing chamber 23 to one of the three exhaust pipes 61, 62, and 63.

As illustrated in FIGS. 1, 3, and 4, the exhaust switching mechanism 25 is disposed between the processing chamber 23 and the three exhaust pipes 61, 62, and 63. The exhaust switching mechanism 25 includes a switching box 71 and three opening/closing mechanisms 73, 74, and 75. The opening/closing mechanisms 73, 74, and 75 are used for the exhaust switching mechanism 25.

The switching box 71 connects the processing chamber 23 to the three exhaust pipes 61, 62, and 63. The switching box 71 connects into the processing chamber 23 via the exhaust inlet 78 of the connecting pipe 76. The connecting pipe 76 connects the processing chamber 23 and the switching box 71. The connecting pipe 76 includes an exhaust control damper (not illustrated). The exhaust control damper adjusts the flow rate (=volume/time) of the gas passing through the connecting pipe 76. One end of the connecting pipe 76 forms an exhaust inlet 78. The gas in the processing chamber 23 is sent from the exhaust inlet 78 into the switching box 71.

The three exhaust pipes 61, 62, and 63 are provided with three communication ports 81, 82, and 83 corresponding to the region of the switching box 71. The first exhaust pipe 61 is provided with a first communication port 81. Similarly, the second exhaust pipe 62 is provided with a second communication port 82. The third exhaust pipe 63 is provided with a third communication port 83. The three communication ports 81, 82, and 83 are aligned in the width direction Y. Each of the three communication ports 81, 82, and 83 is formed in a circular shape.

The three communication ports 81, 82, and 83 communicate the switching box 71 with the three exhaust pipes 61, 62, and 63. That is, the switching box 71 is connected to the first exhaust pipe 61 via the first communication port 81. Similarly, the switching box 71 is connected to the second exhaust pipe 62 via the second communication port 82. The switching box 71 is connected to the third exhaust pipe 63 via the third communication port 83.

The three opening/closing mechanisms 73, 74, and 75 individually open/close the three communication ports 81, 82, and 83. Each of the opening/closing mechanisms 73, 74, and 75 opens/closes one of the three communication ports 81, 82, and 83. Specifically, as illustrated in FIG. 3, the first opening/closing mechanism 73 opens/closes the first communication port 81 (corresponding communication port). Similarly, the second opening/closing mechanism 74 opens/closes the second communication port 82. The third opening/closing mechanism 75 opens and closes the third communication port 83.

Next, a characteristic portion of the present example will be described. As illustrated in FIGS. 3 and 4, the three opening/closing mechanisms 73, 74, and 75 are attached to the switching box 71. If it is difficult to attach and detach the three opening/closing mechanisms 73, 74, and 75, for example, the assembly time of the substrate processing device 1 becomes longer. Therefore, in the exhaust switching mechanism 25 of the present example, each of the three opening/closing mechanisms 73, 74, and 75 is an integrally assembled component having a base member 87 (described later) as a base. This facilitates attachment and detachment of each of the three opening/closing mechanisms 73, 74, and 75.

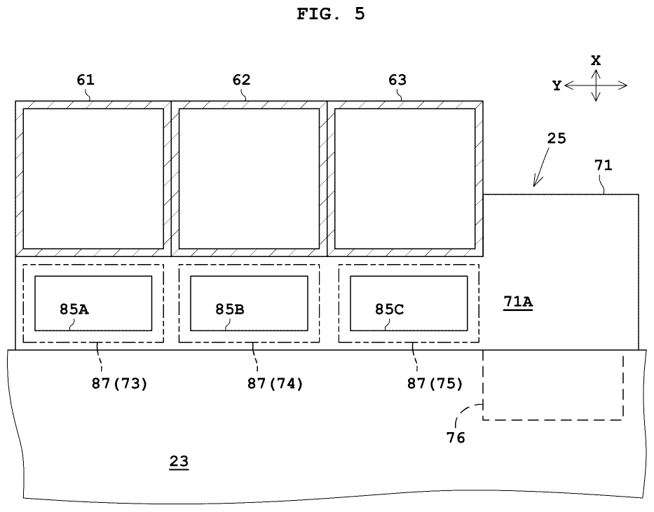

Reference is now made to FIG. 5. The ceiling wall 71A of the switching box 71 includes three attachment openings 85A, 85B, and 85C for attaching the three opening/closing mechanisms 73, 74, and 75 to the ceiling wall 71A. The three attachment openings 85A, 85B, and 85C are provided in the ceiling wall 71A of the switching box 71 in correspondence with the three communication ports 81, 82, and 83. The three attachment openings 85A, 85B, and 85C are arranged in the width direction Y. Each of the attachment openings 85A, 85B, and 85C is formed in a size through which a lid member 95 and a link mechanism 97 provided in a base member 87, described later, can pass.

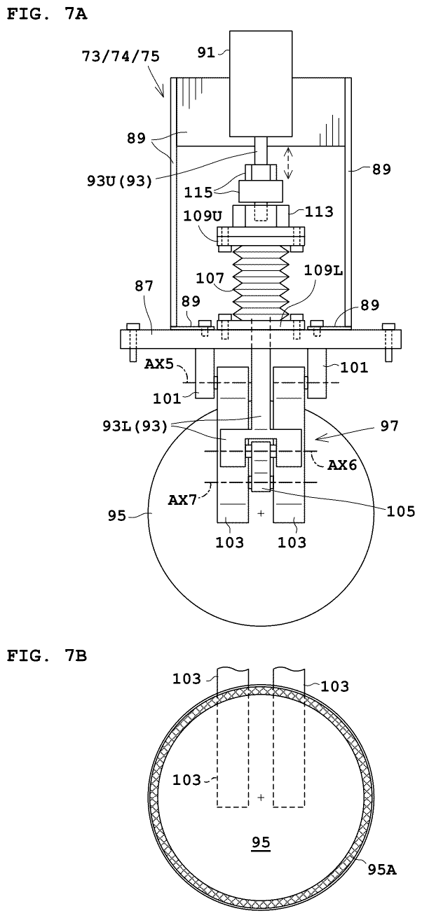

Reference is made to FIGS. 5, 6, and 7A. FIG. 7A is a side view illustrating the first opening/closing mechanism 73 (the second opening/closing mechanism 74 or the third opening/closing mechanism 75) integrally formed with the base member 87 as a base. The three opening/closing mechanisms 73, 74, and 75 are attached to the three attachment openings 85A, 85B, and 85C.

The first opening/closing mechanism 73 is attached to the attachment opening 85A. The second opening/closing mechanism 74 is attached to the attachment opening 85B. The third opening/closing mechanism 75 is attached to the attachment opening 85C. The three opening/closing mechanisms 73, 74, and 75 have substantially the same configuration.

Each of the three opening/closing mechanisms 73, 74, and 75 includes a base member 87, an upper support member 89, an actuator 91, a rod 93, a lid member 95, and a link mechanism 97. The rod 93 includes an upper rod 93U and a lower rod 93L. When the upper rod 93U and the lower rod 93L are not distinguished from each other, they are referred to as “rod 93”.

The base member 87 is attached (assembled) to the ceiling wall 71A while closing one of the three attachment openings 85A, 85B, and 85C. For example, the base member 87 of the first opening/closing mechanism 73 is attached to the ceiling wall 71A while closing the attachment opening 85A. Furthermore, the base member 87 of the second opening/closing mechanism 74 is attached to the ceiling wall 71A while closing the attachment opening 85B. In FIG. 5, the outer shapes of the three base members 87 of the three opening/closing mechanisms 73, 74, and 75 are indicated by two-dot chain lines. The three base members 87 are respectively attached to the three attachment openings 85A, 85B, and 85C with a plurality of screws.

The upper support member 89 is provided on the upper surface of the base member 87. The upper support member 89 is formed in a gate shape, but may not be formed in a gate shape. The actuator 91 is attached to the upper support member 89. That is, the upper support member 89 is a member for fixing the actuator 91 to the base member 87. The actuator 91 includes, for example, an air cylinder, but may include an electric motor.

The rod 93 extends downward from the actuator 91 while penetrating through the base member 87. The rod 93 (upper rod 93U) is moved in the up-down direction Z by the actuator 91. The lid member 95 is disposed below the base member 87.

The lid member 95 is a member that allows gas from the processing chamber 23 to flow or blocks gas from the processing chamber 23 between the inside of the switching box 71 and, for example, the first exhaust pipe 61. A state allowing the gas from the processing chamber 23 to flow is referred to as an open state. In addition, a state for blocking the gas from the processing chamber 23 is referred to as a closed state. The lid member 95 is formed in a disk shape. As illustrated in FIG. 7B, a ring-shaped packing (seal member) 95A is disposed on a peripheral edge portion of a surface (front surface) of the lid member 95 having a circular shape.

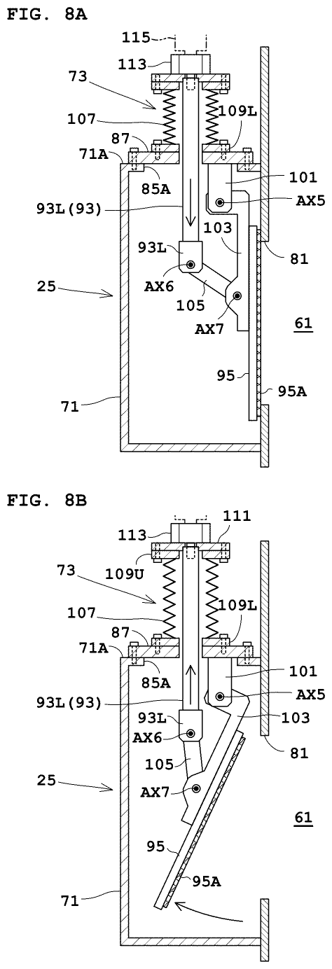

Reference is made to FIGS. 7A, 8A, and 8B. The link mechanism 97 is provided on the lower surface of the base member 87. The link mechanism 97 converts the movement of the rod 93 in the up-down direction Z into the swing of the lid member 95 about the horizontal axis AX5. The link mechanism 97 includes a lower support member 101, a first link 103, and a second link 105. The lower support member 101 is provided on the lower surface of the base member 87. That is, the lower support member 101 is fixed to the lower surface of the base member 87. Note that the first link 103 and the second link 105 correspond to a link member of the present invention.

The horizontal axis AX5 is located at a height between the base member 87 and the lid member 95. The horizontal axis AX5 passes through a lower end portion of the lower support member 101. The horizontal axis AX6 passes through a lower end portion of the rod 93 (93L). The horizontal axis AX7 passes through a lower end side of the first link 103. The horizontal axis AX6 and the horizontal axis AX7 are each parallel to the horizontal axis AX5. That is, the three horizontal axes AX5, AX6, and AX7 each extend in the width direction Y. Furthermore, in a closed state illustrated in FIG. 8A, the horizontal axis AX6 is located at a height between the two horizontal axes AX5 and AX7. Moreover, in the closed state, the horizontal axis AX5 is located between the two horizontal axes AX6 and AX7 in plan view.

An upper end portion of the first link 103 is coupled to the lower end portion of the lower support member 101. The first link 103 is rotatable about a horizontal axis AX5 passing through a portion coupled to the lower support member 101. That is, the first link 103 is rotatable about the horizontal axis AX5. A lower end portion of the first link 103 is coupled to the back surface of the disk-shaped lid member 95. An upper end portion of the second link 105 is coupled to the rod 93 (lower rod 93L) so as to be rotatable about the horizontal axis AX6. A lower end portion of the second link 105 is coupled to the first link 103 so as to be rotatable about the horizontal axis AX7.

Next, a bellows structure of another characteristic portion of the present example will be described. In a portion where the lower rod 93L slides with respect to the base member 87, it is difficult to ensure airtightness. Therefore, when, for example, an acidic gas in the switching box 71 leaks at the sliding portion, there is a possibility that, for example, an electronic device disposed at the periphery thereof may be corroded. Therefore, in the present example, the bellows structure is adopted for the sliding portion. This prevents leakage of gas at the sliding portion.

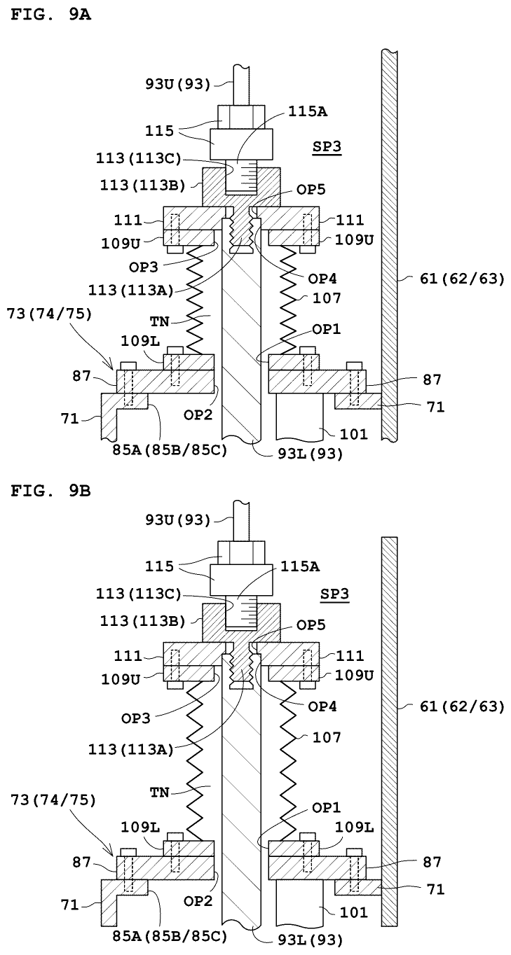

Reference is made to FIGS. 9A and 9B. Each of the three opening/closing mechanisms 73, 74, and 75 includes a bellows 107, a lower flange member 109L, an upper flange member 109U, a lower rod holding member 111, and a coupling screw 113. The lower flange member 109L corresponds to a lower member of the present invention. The upper flange member 109U, the lower rod holding member 111, and the coupling screw 113 correspond to an upper member of the present invention.

The bellows 107 extends in the up-down direction Z. A cavity TN of the bellows 107 can accommodate a part or all of the lower rod 93L. The lower flange member 109L is provided at a lower end of the bellows 107. The lower flange member 109L is formed in a plate shape. An opening OP1 having a size (diameter) through which the lower rod 93L can pass is formed at a central portion of the lower flange member 109L.

An opening OP2 having a size (diameter) through which the lower rod 93L can pass is also formed in the base member 87. Each of the two openings OP1 and OP2 is formed in a circular shape. The lower flange member 109L is attached to the upper surface of the base member 87 with, for example, a plurality of screws. The lower rod 93L passes through the lower flange member 109L and the base member 87 while passing through the cavity TN of the bellows 107.

The upper flange member 109U is provided at an upper end of the bellows 107. An opening OP3 having a size (diameter) through which the lower rod 93L can pass is formed in the upper flange member 109U. That is, the cavity TN inside the bellows 107 can be accessed only from the two openings OP1 and OP3.

The lower rod holding member 111 is attached to the upper surface of the upper flange member 109U with, for example, a plurality of screws. A hole portion OP4 slightly larger than the diameter of the lower rod 93L is formed in the central portion of the lower rod holding member 111 and on the lower surface of the lower rod holding member 111. On the upper surface of the lower rod holding member 111, an opening OP5 having a size that the lower rod 93L cannot pass through is formed. Furthermore, the opening OP5 is formed to have a size that allows the screw portion (outer screw portion) 113A of the coupling screw 113 to pass therethrough and a size that does not allow the head portion 113B of the coupling screw 113 to pass therethrough. In plan view, the center of the opening OP5 preferably coincides with the centers of the opening OP3 and the hole portion OP4.

The lower rod holding member 111 regulates the movement of the lower rod 93L in the horizontal direction (the front-back direction X and the width direction Y) by accommodating an upper end of the lower rod 93L in the hole portion OP4. Furthermore, the coupling screw 113 is fastened to a screw hole (inner screw) provided in an upper end face of the lower rod 93L while sandwiching the lower rod holding member 111 between the head portion 113B and the lower rod 93L.

As a result, the upper end of the lower rod 93L is coupled to an upper member (upper flange member 109U, lower rod holding member 111, and coupling screw 113). The upper member (upper flange member 109U, lower rod holding member 111, and coupling screw 113) is provided at the upper end of the bellows 107 so as to close an upper end of the cavity TN. The lower rod 93L, the upper flange member 109U, the lower rod holding member 111, and the coupling screw 113 are integrally moved.

As illustrated in FIGS. 9A and 9B, the lower rod 93L is moved up and down with respect to the base member 87. At this time, gas can move between the inside of the switching box 71 and the inside of the cavity TN of the bellows 107. However, since the upper end of the bellows 107 is closed, the space in the cavity TN is isolated with respect to the space SP3 outside the bellows 107. That is, the gas in the cavity TN is prevented from leaking into the space SP3.

The upper rod 93U extends downward from the actuator 91. The upper rod 93U is moved in the up-down direction Z by the actuator 91. A lower end of the upper rod 93U is coupled to the upper member (upper flange member 109U, lower rod holding member 111, and coupling screw 113) by way of a floating joint 115. The floating joint 115 is a joint that absorbs eccentricity and deflection angle between the upper rod 93U and the lower rod 93L.

Specifically, the lower end of the upper rod 93U is coupled to an upper portion of the floating joint (joint) 115. A screw portion 115A of the floating joint 115 is fastened to a screw hole 113C formed in an upper surface of the coupling screw 113. As a result, the floating joint 115 is coupled to the coupling screw 113 and is coupled to the upper rod 93U.

Here, operations of the three opening/closing mechanisms 73, 74, and 75 will be briefly described. As shown in FIG. 8B, the actuator 91 moves the rod 93 (upper rod 93U and lower rod 93L) upward. As a result, the lid member 95 is brought into an open state for allowing the gas from the processing chamber 23 to flow. When the lid member 95 of the first opening/closing mechanism 73 is in the open state, the first communication port 81 is opened. Similarly, when the lid member 95 of the second opening/closing mechanism 74 is in the open state, the second communication port 82 is opened. Furthermore, when the lid member 95 of the third opening/closing mechanism 75 is in the open state, the third communication port 83 is opened.

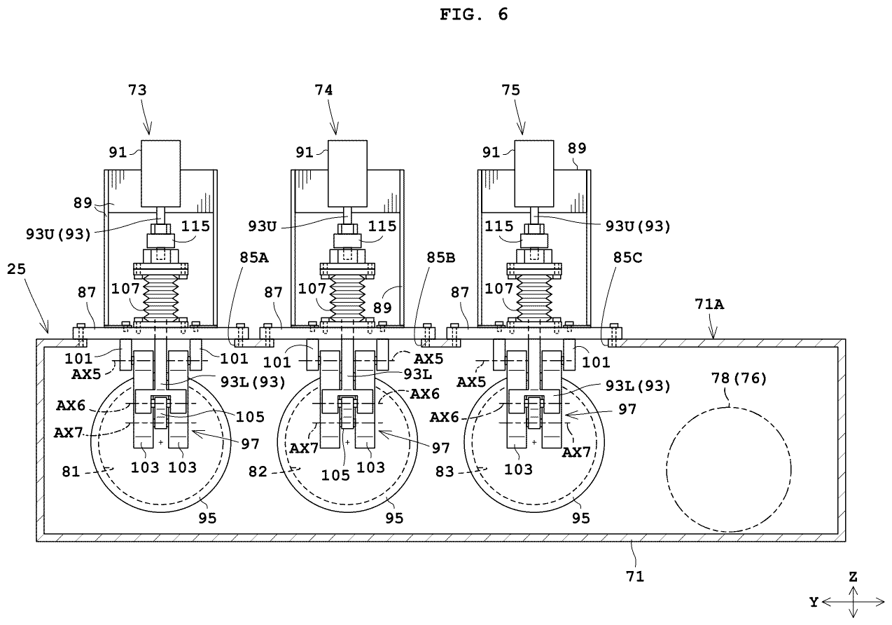

As illustrated in FIG. 8A, the actuator 91 moves the rod 93 downward. As a result, the lid member 95 is brought into a closed state for blocking gas from the processing chamber 23. When the lid member 95 of the first opening/closing mechanism 73 is in the closed state, the first communication port 81 is closed. Similarly, when the lid member 95 of the second opening/closing mechanism 74 is in the closed state, the second communication port 82 is closed. Furthermore, when the lid member 95 of the third opening/closing mechanism 75 is in the closed state, the third communication port 83 is closed. Note that the opening/closing mechanisms 73, 74, and 75 illustrated in FIGS. 6 and 7A are in the closed state.

The horizontal axis AX5 corresponds to a first horizontal axis of the present invention. The horizontal axis AX6 corresponds to a second horizontal axis of the present invention. The horizontal axis AX7 corresponds to a third horizontal axis of the present invention. The upper rod 93U corresponds to a first rod of the present invention. The lower rod 93L corresponds to a second rod of the present invention.

### <4. Control Unit>

The substrate processing device 1 includes a control unit 120 (see FIG. 1) and a storage unit (not illustrated). The control unit 120 controls each configuration of the substrate processing device 1. The control unit 120 includes one or more processors such as a central processing unit (CPU). The storage unit includes, for example, at least one of a read-only memory (ROM) and a random-access memory (RAM). The storage unit stores a computer program necessary for controlling each configuration of the substrate processing device 1.

### <5. Operation of Substrate Processing Device>

Next, an operation of the substrate processing device 1 will be described. Reference is now made to FIG. 1. The carrier C is transported in the load port LP. The indexer robot IR takes out the substrate W from the carrier C transported to the load port LP and transports the substrate W to the substrate placing portion PS.

The transport robot TR of the processing block 3 takes out the substrate W from the substrate placing portion PS, and transports the substrate W to one of the twenty-four processing chambers 23 (twenty-four processing units 21). For example, it is assumed that the substrate W is sent to a predetermined processing chamber 23 of the second tower TW2. At this time, the substrate W is transported onto the holding and rotating unit 27 of the predetermined processing chamber 23 through the substrate transport port 30. The holding and rotating unit 27 holds the transported substrate W. After the substrate W is transported onto the holding and rotating unit 27, the substrate transport port 30 is closed by a shutter (not illustrated).

The fan filter unit 31 illustrated in FIG. 4 supplies clean air into the processing chamber 23. In addition, an exhaust facility of the factory takes in gas from one end of each of the six horizontal exhaust pipes 65A, 66A, 67A, 65B, 66B, and 67B. For example, in the exhaust switching mechanism 25 illustrated in FIGS. 3 and 6, the two opening/closing mechanisms 73 and 74 close the two communication ports 81 and 82, and the third opening/closing mechanism 75 opens the third communication port 83. Therefore, the gas in the predetermined processing chamber 23 is sent to the exhaust facility of the factory via the third communication port 83, the third exhaust pipe 63, and the horizontal exhaust pipe 67A.

For example, the first exhaust pipe 61 is used for exhausting an acidic gas. The second exhaust pipe 62 is used for exhausting an alkaline gas. The third exhaust pipe 63 is used for exhausting an organic gas. Furthermore, for example, the second exhaust pipe 62 may be used for exhausting an organic gas, and the third exhaust pipe 63 may be used for exhausting an alkaline gas. The role of the three exhaust pipes 61, 62, and 63 is not limited.

### <5-1. Exhaust Operation of Predetermined Processing Unit>

First, a case where an acidic chemical solution (first chemical solution) is supplied to the substrate W to perform chemical solution treatment will be described. In the exhaust switching mechanism 25 illustrated in FIGS. 3 and 6, the first opening/closing mechanism 73 opens the first communication port 81, and the two opening/closing mechanisms 74 and 75 close the two communication ports 82 and 83. As a result, the gas in the predetermined processing chamber 23 is sent to the connecting pipe 76 (exhaust inlet 78), the switching box 71, and the first exhaust pipe 61 in this order. For example, the upper end of the first exhaust pipe 61 is connected to the horizontal exhaust pipe 65A. Therefore, the gas sent to the first exhaust pipe 61 is sent to the exhaust facility of the factory via the horizontal exhaust pipe 65A.

Thereafter, the first rotation driving unit 35A rotates the first nozzle 29A about the vertical axis AX2. As a result, the distal end portion 33A of the first nozzle 29A is moved from the standby position on the outer side of the substrate W to above the substrate W held by the holding and rotating unit 27. Thereafter, the acidic chemical solution is discharged from the first nozzle 29A by opening the open/close valve V1. Furthermore, the holding and rotating unit 27 rotates the substrate W to be held about the vertical axis AX1. Due to the discharge of the acidic chemical solution, a mist (or vapor) of the acidic chemical solution is generated in the processing chamber 23. The gas containing the mist of the acidic chemical solution is sent to the first exhaust pipe 61 through the switching box 71.

In addition, a case where an alkaline chemical solution (second chemical solution) is supplied to the substrate W to perform chemical solution treatment will be described. In the exhaust switching mechanism 25 illustrated in FIGS. 3 and 6, the second opening/closing mechanism 74 opens the second communication port 82, and the two opening/closing mechanisms 73 and 75 close the two communication ports 81 and 83. As a result, the gas in the predetermined processing chamber 23 is sent to the connecting pipe 76 (exhaust inlet 78), the switching box 71, and the second exhaust pipe 62 in this order. For example, the upper end of the second exhaust pipe 62 is connected to the horizontal exhaust pipe 66A. Therefore, the gas sent to the second exhaust pipe 62 is sent to the exhaust facility of the factory via the horizontal exhaust pipe 66A.

Thereafter, the second rotation driving unit 35B rotates the second nozzle 29B about the vertical axis AX3. As a result, the distal end portion 33B of the second nozzle 29B is moved to above the substrate W held by the holding and rotating unit 27. Thereafter, the alkaline chemical solution is discharged from the second nozzle 29B by opening the open/close valve V2. Furthermore, the holding and rotating unit 27 rotates the substrate W to be held about the vertical axis AX1. Due to the discharge of the alkaline chemical solution, a mist (or vapor) of the alkaline chemical solution is generated in the processing chamber 23. The gas containing the mist of the alkaline chemical solution is sent to the second exhaust pipe 62 through the switching box 71.

In addition, a case where an organic chemical solution (third chemical solution) is supplied to the substrate W to perform chemical solution treatment will be described. In the exhaust switching mechanism 25 illustrated in FIGS. 3 and 6, the third opening/closing mechanism 75 opens the third communication port 83, and the two opening/closing mechanisms 73 and 74 close the two communication ports 81 and 82. As a result, the gas in the predetermined processing chamber 23 is sent to the connecting pipe 76 (exhaust inlet 78), the switching box 71, and the third exhaust pipe 63 in this order. For example, the upper end of the third exhaust pipe 63 is connected to the horizontal exhaust pipe 67A. Therefore, the gas sent to the third exhaust pipe 63 is sent to the exhaust facility of the factory via the horizontal exhaust pipe 67A.

Thereafter, the third rotation driving unit 35C rotates the third nozzle 29C about the vertical axis AX4. As a result, the distal end portion 33C of the third nozzle 29C is moved to above the substrate W held by the holding and rotating unit 27. Thereafter, the organic chemical solution is discharged from the third nozzle 29C by opening the open/close valve V3. Furthermore, the holding and rotating unit 27 rotates the substrate W to be held about the vertical axis AX1. Due to the discharge of the organic chemical solution, a mist (or vapor) of the organic chemical solution is generated in the processing chamber 23. The gas containing the mist of the organic chemical solution is sent to the third exhaust pipe 63 through the switching box 71.

After the chemical solution treatment is performed on the substrate W in a predetermined processing chamber 23, a shutter (not illustrated) is moved to open the substrate transport port 30 of the processing chamber 23. The transport robot TR transports the substrate W from the processing chamber 23 to the substrate placing portion PS through the substrate transport port 30. The indexer robot IR transports the substrate W subjected to the chemical solution treatment from the substrate placing portion PS to the carrier C of the load port LP.

According to the present example, the base member 87 detachably attached (attachable (assembled) and detachable) to the three attachment openings 85A, 85B, and 85C provided in the ceiling wall 71A of the switching box 71 in correspondence with the three communication ports 81, 82, and 83 is provided. The base member 87 is integrally provided with the upper support member 89, the actuator 91, the rod 93 (93U, 93L), the lid member 95, and the link mechanism 97 (lower support member 101, first link 103, and second link 105). Therefore, the opening/closing mechanisms 73, 74, and 75 integrated with each other can be attached to and detached from the switching box 71. Therefore, attachment and detachment of the opening/closing mechanisms 73, 74, and 75 can be facilitated.

Furthermore, the lower flange member 109L provided at the lower end of the bellows 107 is attached to the base member 87. The upper member (upper flange member 109U, lower rod holding member 111, and coupling screw 113) provided at the upper end of the bellows 107 closes the upper end of the cavity TN of the bellows 107. Furthermore, the upper rod 93U is coupled to the lower rod 93L by way of the upper member. The lower rod 93L passes through the lower flange member 109L and the base member 87 while passing through the cavity TN of the bellows 107. With such a bellows 107 and its peripheral structure, even if there is a sliding portion of the rod 93 (93L) with respect to the base member 87, gas in the switching box 71 can be prevented from leaking.

The floating joint 115 interposed between the lower end of the upper rod 93U and the upper member (upper flange member 109U, lower rod holding member 111, and coupling screw 113) can absorb the eccentricity and deflection angle between the upper rod 93U and the lower rod 93L.

When the lid member 95 is in the closed state, airtightness is improved by the packing 95A. For example, mixture of gas containing a chemical solution (chemical solution atmosphere) into another exhaust line can be prevented. As a result, for example, when a part of the organic exhaust line is made of metal such as stainless steel, it is possible to prevent corrosion of the metal portion due to mixing of the acidic exhaust air.

The present invention is not limited to the above example, and can be modified as follows.

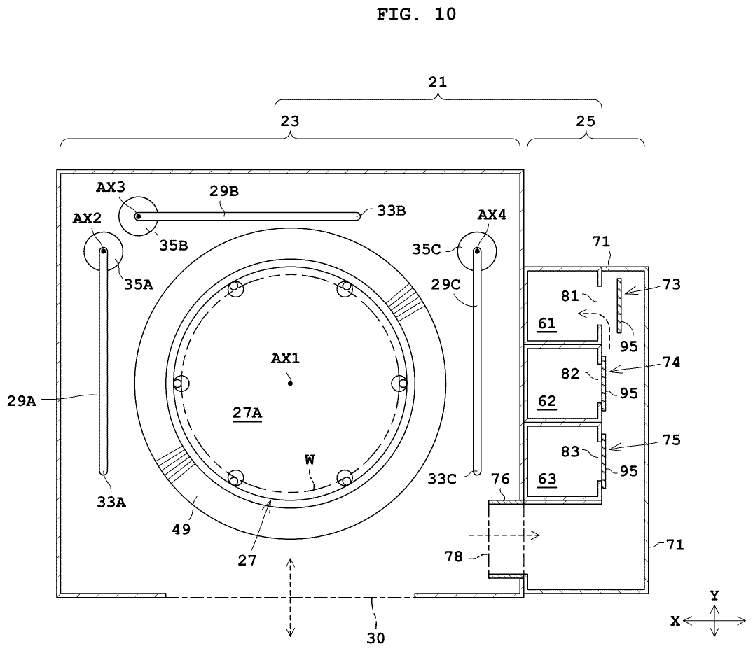

(1) In the above-described example, as illustrated in FIG. 4, the exhaust switching mechanism 25 (in particular, three opening/closing mechanisms 73, 74, 75) is disposed between the processing chamber 23 and the three exhaust pipes 61, 62, and 63. In this regard, as illustrated in FIG. 10, the three exhaust pipes 61, 62, and 63 may be disposed between the processing chamber 23 and the three opening/closing mechanisms 73, 74, and 75.

(2) In the above-described example and modified example (1), the floating joint 115 is provided between the upper rod 93U and the coupling screw 113. For example, if there is no need to absorb the eccentricity and deflection angle between the upper rod 93U and the lower rod 93L, the floating joint 115 may not be provided. In this case, the lower end of the upper rod 93U is coupled to the coupling screw 113 without the floating joint 115 interposed therebetween.

(3) In the above-described example and each modified example, each of the opening/closing mechanisms 73, 74, and 75 includes the floating joint 115. In this respect, the floating joint 115 may be replaced with another joint that absorbs at least one of eccentricity and deflection angle between the upper rod 93U and the lower rod 93L.

(4) In the above-described example and each modified example, each processing chamber 23 includes three nozzles 29A, 29B, and 29C. In this regard, each processing chamber 23 may, for example, not include the nozzle 29C, but include two nozzles 29A and 29B. That is, each processing chamber 23 may include a plurality of nozzles.

(5) In the above-described example and each modified example, each of the opening/closing mechanisms 73, 74, and 75 includes the bellows 107, a lower member (lower flange member 109L), and the upper member (upper flange member 109U, lower rod holding member 111, and coupling screw 113). In this regard, for example, when sufficient airtightness can be ensured at the sliding portion of the rod 93 with respect to the base member 87, each of the opening/closing mechanisms 73, 74, and 75 may not include the bellows 107, the lower member, and the upper member. In this case, for example, the upper rod 93U is coupled to the lower rod 93L by way of the floating joint 115.

(6) In the above-described example and each modified example, three exhaust pipes 61, 62, and 63 are provided on the side of the processing chamber 23, but the number of exhaust pipes is not limited to three. That is, a plurality of exhaust pipes may be provided on the side of the processing chamber 23. In addition, a plurality of (for example, two) opening/closing mechanisms for individually opening/closing a plurality of (for example, two) communication ports may be attached to the switching box 71 in correspondence with a plurality of (for example, two) exhaust pipes.

(7) In the above-described example and each modified example, for example, as shown in FIG. 4, the lid member 95 is in direct contact with the third exhaust pipe 63 in order to close the third communication port 83. For example, it is assumed that a side wall having an opening communicating with the third communication port 83 is provided between the lid member 95 and the third exhaust pipe 63 in some cases. In this case, the lid member 95 may close the opening to close the third communication port 83.

(8) In the above-described example and each modified example, it is assumed that the lower end portion of the lower rod 93L is coupled to the upper end portion of the second link 105. At this time, the coupling screw 113 is fastened to a screw hole provided in the upper end face of the lower rod 93L while sandwiching the lower rod holding member 111 between the head portion 113B of the coupling screw 113 and the lower rod 93L. Thereafter, the lower rod holding member 111 may be attached to the upper surface of the upper flange member 109U with, for example, a plurality of screws. Consequently, lower rod 93L can easily be coupled to coupling screw 113.

The present invention may be embodied in other specific forms without departing from the spirit or essential attributes thereof and, accordingly, reference should be made to the appended claims, rather than to the foregoing specification, as indicating the scope of the invention.

What is claimed is:

1. An opening/closing mechanism that is used in an exhaust switching mechanism that connects a processing chamber to any of a plurality of exhaust pipes via a switching box, and that opens/closes any one of a plurality of communication ports for communicating the switching box and the plurality of exhaust pipes, the opening/closing mechanism comprising:
a base member attachable to each of a plurality of attachment openings provided in a ceiling wall of the switching box in correspondence with the plurality of communication ports;
an upper support member provided on an upper surface of the base member;
an actuator attached to the upper support member;
a rod extending downward from the actuator while penetrating the base member, the rod being moved in an up-down direction by the actuator;
a lower support member provided on a lower surface of the base member;
a lid member provided below the base member and configured to close the one of the communication ports; and
a link member provided below the base member to connect the rod, the lower support member, and the lid member,
wherein the lid member is switched between an open state and a closed state when movement of the rod in the up-down direction is transmitted to the lid member via the link member.

2. The opening/closing mechanism according to claim 1, wherein
the link member includes:
a first link having an upper end portion coupled to a lower end portion of the lower support member to be rotatable about a first horizontal axis passing through a portion coupled to the lower support member, the first link having a lower end portion coupled to a back surface of the lid member; and
a second link having an upper end portion coupled to the rod to be rotatable about a second horizontal axis passing through a lower end portion of the rod, the second link having a lower end portion coupled to the first link to be rotatable about a third horizontal axis passing through the first link, and
each of the second horizontal axis and the third horizontal axis is parallel to the first horizontal axis.

3. The opening/closing mechanism according to claim 1, further comprising:
a bellows extending in the up-down direction;
a lower member provided at a lower end of the bellows and attached to the base member; and
an upper member provided at an upper end of the bellows to close an upper end of a cavity of the bellows,
wherein the rod includes a first rod and a second rod,
the first rod extends downward from the actuator, and a lower end of the first rod is coupled to the upper member,
an upper end of the second rod is coupled to the upper member, and
the second rod penetrates the lower member and the base member while passing through the cavity of the bellows.

4. The opening/closing mechanism according to claim 3, wherein
the lower end of the first rod is coupled to the upper member by way of a joint that absorbs eccentricity and deflection angle between the first rod and the second rod.

5. The opening/closing mechanism according to claim 1, wherein
a packing is disposed on a peripheral edge portion of a surface of the lid member.

6. An exhaust switching mechanism that switches an exhaust path from a processing chamber to any of a plurality of exhaust pipes, the exhaust switching mechanism comprising:
a switching box that connects the processing chamber to the plurality of exhaust pipes; and
a plurality of opening/closing mechanisms that individually opens/closes a plurality of communication ports for communicating the switching box and the plurality of exhaust pipes, the plurality of opening/closing mechanisms being attached to a plurality of attachment openings provided in a ceiling wall of the switching box in correspondence: with the plurality of communication ports,
wherein each of the plurality of opening/closing mechanisms includes:
a base member attachable to each of the plurality of attachment openings;
an upper support member provided on an upper surface of the base member;
an actuator attached to the upper support member;
a rod extending downward from the actuator while penetrating the base member, the rod being moved in an up-down direction by the actuator;
a lower support member provided on a lower surface of the base member;
a lid member provided below the base member and configured to close a corresponding one of the plurality of communication ports; and
a link member provided below the base member to connect the rod, the lower support member, and the lid member, and
the lid member is switched between an open state and a closed state when movement of the rod in the up-down direction is transmitted to the lid member via the link member.

7. A substrate processing device that processes a substrate, the substrate processing device comprising:
an exhaust switching mechanism that switches an exhaust path from a processing chamber to any of a plurality of exhaust pipes;
the processing chamber;
a holding unit provided in the processing chamber to hold the substrate in a horizontal posture;
a nozzle provided in the processing chamber and configured to discharge chemical solution to the substrate held by the holding unit; and
the plurality of exhaust pipes provided at a side of the processing chamber and extending in an up-down direction, wherein
the exhaust switching mechanism includes:
a switching box that connects the processing chamber to the plurality of exhaust pipes; and
a plurality of opening/closing mechanisms that individually opens/closes a plurality of communication ports for communicating the switching box and the plurality of exhaust pipes, the plurality of opening/closing mechanisms being attached to a plurality of attachment openings provided in a ceiling wall of the switching box in correspondence with the plurality of communication ports,
each of the plurality of opening/closing mechanisms includes:
a base member attachable to each of the plurality of attachment openings;
an upper support member provided on an upper surface of the base member;
an actuator attached to the upper support member;
a rod extending downward from the actuator while penetrating the base member, the rod being moved in the up-down direction by the actuator;
a lower support member provided on a lower surface of the base member;
a lid member provided below the base member and configured to close a corresponding one of the plurality of communication ports; and
a link member provided below the base member to connect the rod, the lower support member, and the lid member, and
the lid member is switched between an open state and a closed state when movement of the rod in the up-down direction is transmitted to the lid member via the link member.
